(19) United States
(12) Patent Application Publication
(10) Pub. No.: US 2025/0251285 A1
(43) Pub. Date: Aug. 7, 2025

(54) SUBSTRATE PROCESSING SYSTEMS, METHODS, AND RELATED APPARATUS AND CHAMBERS, FOR DETECTING PROCESSING SHIFTS

(71) Applicant: Applied Materials, Inc., Santa Clara, CA (US)

(72) Inventors: Saurabh CHOPRA, Santa Clara, CA (US); Khokan C. PAUL, Cupertino, CA (US); Zhepeng CONG, San Jose, CA (US)

(21) Appl. No.: 18/605,175

(22) Filed: Mar. 14, 2024

Related U.S. Application Data
(60) Provisional application No. 63/548,813, filed on Feb. 1, 2024.

(51) Int. Cl. G01J 5/00; G01J 5/08; H01L 21/67

(52) U.S. Cl. CPC G01J 5/0007; G01J 5/0814; H01L 21/67248

(57) ABSTRACT

Embodiments of the present disclosure relate to substrate processing systems, methods, and related apparatus and chambers for detecting processing shifts. In one or more embodiments, a system for processing substrates includes a chamber body. The system includes one or more heat sources operable to heat a processing volume, a substrate support disposed in the processing volume, and a sensor operable to measure an emissivity in the processing volume. The system includes a controller including instructions that, when executed by a processor, cause a plurality of operations to be conducted. The plurality of operations include analyzing the measured emissivity for a time period. The analyzing includes generating a signal profile of the measured emissivity over the time period. The plurality of operations include detecting a shift in the signal profile along a shift section of the signal profile and adjusting a process parameter in response to the detection of the shift.

### CROSS-REFERENCE TO RELATED APPLICATION

This application claims priority to U.S. provisional patent application Ser. No. 63/548,813, filed Feb. 1, 2024, which is herein incorporated by reference in its entirety.

### BACKGROUND

Embodiments of the present disclosure relate to substrate processing systems, methods, and related apparatus and chambers for detecting processing shifts.

### DESCRIPTION OF THE RELATED ART

Semiconductor substrates are processed for a wide variety of applications, including the fabrication of integrated devices and microdevices. Precise control over a heating source allows a substrate to be heated within tolerances. The temperature of the substrate can affect the uniformity of the material deposited on the substrate. It can be difficult to measure and/or adjust process parameters, such as temperature and/or film growth, in a real-time manner. Calibration methods can involve opening of the process chamber and machine down time.

Therefore, a need exists for improved systems, methods, and apparatus.

### SUMMARY

Embodiments of the present disclosure relate to substrate processing systems, methods, and related apparatus and chambers for detecting processing shifts.

In one or more embodiments, a system for processing substrates includes a chamber body. The chamber body at least partially defines a processing volume. The system includes one or more heat sources operable to heat the processing volume, a substrate support disposed in the processing volume, and a sensor operable to measure an emissivity in the processing volume. The system includes a controller including instructions that, when executed by a processor, cause a plurality of operations to be conducted. The plurality of operations include analyzing the measured emissivity for a time period. The analyzing includes generating a signal profile of the measured emissivity over the time period. The plurality of operations include detecting a shift in the signal profile along a shift section of the signal profile and adjusting a process parameter in response to the detection of the shift.

In one or more embodiments, a method of monitoring substrate processing includes directing energy from an energy source toward a surface in a processing chamber, and receiving emitted energy using a sensor. The method includes analyzing the emitted energy for a time period. The analyzing includes measuring an emissivity of the emitted energy over the time period to generate a signal profile. The method includes detecting a shift in the emitted energy over the time period, and adjusting a process recipe in response to the shift in the emitted energy.

In one or more embodiments, a non-transitory computer readable medium includes instructions that, when executed, cause a plurality of operations to be conducted. The plurality of operations include measuring an emissivity over a time period to generate a signal profile, and detecting a shift in the signal profile along a shift section of the signal profile. The plurality of operations include adjusting a process parameter in response to the detection of the shift.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a processing system, according to one or more embodiments.

FIG. 2 is a partial schematic cross-sectional view of an in-situ reflectometry system (ISR) that can be used as at least part of the measurement assembly, according to one or more embodiments.

FIG. 3 is a schematic flow diagram view of a method of monitoring substrate processing, according to one or more embodiments.

FIGS. 4A-4D schematically illustrate a process flow of a substrate processing operation, according to one or more embodiments.

FIGS. 5A-5D schematically illustrate a process flow of a substrate processing operation, according to one or more embodiments.

FIGS. 6A-6C schematically illustrate a process flow of a substrate processing operation, according to one or more embodiments.

FIGS. 7A-7C schematically illustrate a process flow of a substrate processing operation, according to one or more embodiments.

FIG. 8 is a schematic graphical view of a reference profile, according to one or more embodiments.

FIG. 9 is a schematic graphical view of a signal profile, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to substrate processing systems, methods, and related apparatus and chambers for detecting processing shifts. In one or more embodiments, a sensor is used to take measurements and generate a signal profile of the measurements. The measurements can be sent to a feedback control loop. A shift can be detected in the signal profile, and the shift can be used to adjust a process recipe. The adjusted process recipe can be used to optimize processing in an in-situ and real-time manner. The process recipe can be adjusted, for example, in relation to smaller processing volumes and/or changing processing volumes.

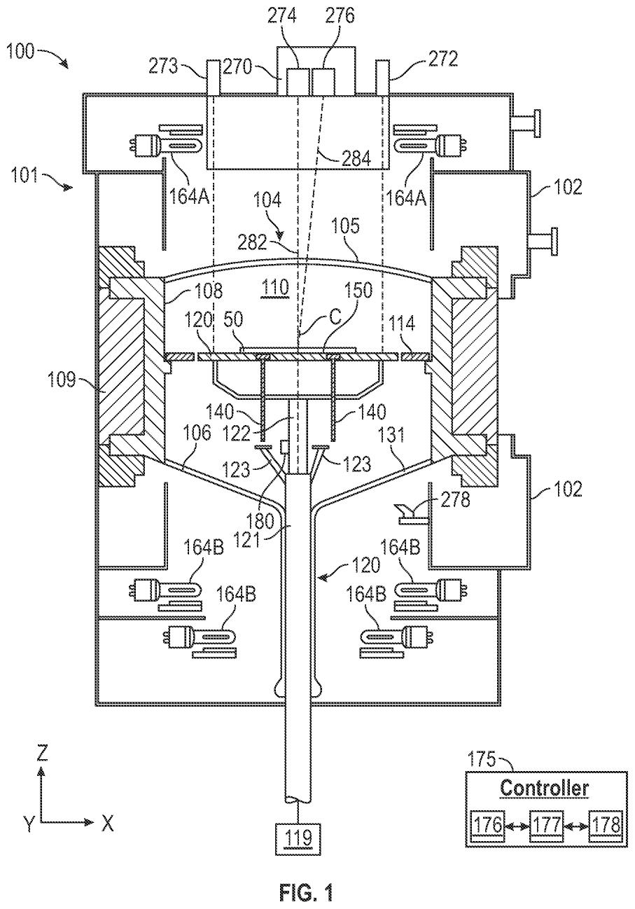

FIG. 1 is a schematic cross-sectional view of a processing system 100, according to one or more embodiments. The processing system 100 includes a process chamber 101 and a controller 175. The processing system 100 can be configured to conduct epitaxial deposition processes in the process chamber 101.

The process chamber 101 includes a housing structure 102 made of a process resistant material, such as aluminum or stainless steel, for example 316L stainless steel. The housing structure 102 can be at least part of a chamber body. The housing structure 102 encloses various functioning elements of the process chamber 101, such as a quartz chamber 104, which includes an upper quartz window 105 and a lower quartz window 131. The quartz chamber 104 encloses an interior volume 110 (also referred to as process volume). One or more liners 108, 109 can protect the housing structure 102 from reactive chemistry and/or can insulate the quartz chamber 104 from the housing structure 102. The process chamber 101 includes a substrate support 120. A substrate 50 can be positioned on the substrate support 120 during processing, such as during depositions.

The process chamber 101 can further include upper heat sources 164A and lower heat sources 164B for heating of the substrate 50 and/or the interior volume 110. The heat sources 164A, 164B can be radiant heat sources such as lamps, for example halogen lamps and/or infrared (IR) lamps. In one or more embodiments, the heat sources 164A, 164B are operable to emit IR light and/or ultraviolet light. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 120 is coupled to an actuator 119, an outer shaft 121, and inner shaft 122. The actuator 119 is configured to vertically move the inner shaft 122 relative to the outer shaft 121. The actuator 119 is further configured to rotate the inner shaft 122 while the outer shaft 121 remains stationary. The inner shaft 122 is configured to rotate about a central axis C extending in the vertical direction through the center of the inner shaft 122.

In one or more embodiments, the substrate support 120 is formed of an opaque material (such as white quartz, grey quartz, quartz with impregnated particles (such as SiC particles or silicon particles), black quartz, silicon carbide (SiC), and/or graphite coated with SiC). The process chamber 101 can include a preheat ring 114 that can be positioned around the substrate support 120, and a plurality of lift pins 140. The lift pins 140 can be formed of quartz (such as transparent quartz). The lift pins 140 can be positioned and configured to lift a substrate 50 above the substrate support 120 to allow the substrate 50 to be transferred to and from the interior volume 110 of the process chamber 101. Lift pin pads 123 can be attached to the outer shaft 121. More or less lift pin pads (e.g., two lift pin pads) can be used. In one or more embodiments, the lift pin pads 123 are formed of quartz (such as transparent quartz). The lift pin pads 123 can be positioned 120 degrees apart from each other relative to the central axis C that extends through a center of the outer shaft 121.

The actuator 119 can lower the inner shaft 122 causing the lift pins 140 to contact the lift pin pads 123 and push the substrate 50 above the substrate support 120. In one or more embodiments, one or more of the lift pin pads 123 can include a sensor (e.g., a proximity sensor) connected to the controller 175 to detect when one or more of the lift pins 140 overlies one or more of the lift pin pads 123. The controller 175 can use the feedback from the sensor to stop the rotation of the substrate support 120 by the actuator 119. This can enable the controller to align the first plurality of lift pins 140A to overlie the lift pin pads 123 for lifting the substrate 50.

In one or more embodiments, the process chamber 101 can include an encoder 180. In one or more embodiments, the encoder can be attached to an outside of the inner shaft 122, such as near a bottom of the inner shaft 122. The encoder 180 can be used to control the angular amount (e.g., 60 degrees, 90 degrees, 180 degrees, etc.) from a home position that the substrate support 120 has rotated. Determining and controlling this angular rotation of the inner shaft 122 enables the substrate support 120 to be rotated to any angle from a home position, which provides the capability for the substrate support 120 and substrate 50 to be rotated to angular positions and/or using angular speeds.

The processing system 100 also includes the controller 175 for controlling processes performed by the processing system 100. The controller 175 can be any type of controller used in an industrial setting, such as a programmable logic controller (PLC). The controller 175 includes a processor 177, a memory 176, and input/output (I/O) circuits 178. The controller 175 can include one or more of the following components, such as one or more power supplies, clocks, communication components (e.g., network interface card), and user interfaces typically found in controllers for semiconductor equipment.

The memory 176 can include a non-transitory memory (e.g., a non-transitory computer readable medium). The non-transitory memory can be used to store the programs and settings described below. The memory 176 can include one or more readily available types of memory, such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote.

The processor 177 is configured to execute various programs stored in the memory 176, such as epitaxial deposition processes and processes for transferring substrates and susceptors into and out of the interior volume 110. During execution of these programs, the controller 175 can communicate to I/O devices through the I/O circuits 178. For example, during execution of these programs and communication through the I/O circuits 178, the controller 175 can control outputs, such as the rotational position of substrate support 120 relative to the lift pin pads 123 and the vertical position of the substrate support 120 through use of the actuator 119. The memory 176 can further include various operational settings used to control the processing system 100.

The controller 175 is configured to conduct any of the operations described herein. In one or more embodiments, the instructions stored on the memory 176, when executed, cause one or more of operations of method 300 (described below) to be conducted in relation to the processing chamber 101. The various operations described herein (such as the operations of the method 300) can be conducted automatically using the controller 175, or can be conducted automatically or manually with certain operations conducted by a user.

The instructions stored in the memory 176 of the controller 175 can include one or more machine learning/artificial intelligence algorithms that can be executed in addition to the operations described herein. As an example, a machine learning/artificial intelligence algorithm executed by the controller 175 can generate, prioritize, accept, and/or reject reference profiles and/or signal profiles used in relation to the method 300. The machine learning/artificial intelligence algorithm can account for previous operational runs to monitor and update the reference profiles. The machine learning/artificial intelligence algorithm can select and/or adjust the deviation used to detect the profess shift in operation 310. The machine learning/artificial intelligence algorithm can optimize the adjusted process parameter(s) of the adjusted process recipe. The one or more machine learning/artificial intelligence algorithms can use, for example, a regression model (such as a linear regression model) or a clustering technique to estimate optimized parameters and/or optimized values for signal profiles and/or reference profiles. The algorithm(s) can be unsupervised or supervised. In one or more embodiments, the controller 175 automatically conducts the operations described herein without the use of one or more machine learning/artificial intelligence algorithms. In one or more embodiments, the controller 175 compares measurements to data in a look-up table and/or a library to determine if the shift is detected in operation 310. The controller 175 can store measurements as data in the look-up table and/or the library.

The processing system 100 includes a measurement assembly 270 including a sensor 276. In one or more embodiments, the processing system 100 includes a second sensor 272 and/or a third sensor 273. In one or more embodiments, the sensor 276 includes a reflectometer, the second sensor 272 includes a growth rate sensor and/or a temperature sensor, and/or a third sensor 273 includes a growth rate sensor and/or a temperature sensor. The controller 175 can control the measurement assembly 270 and/or the sensor(s) 272, 273, and adjust a process recipe of processing conducted using the processing chamber 101. In one or more embodiments, the sensors 272, 273 respectively include a pyrometer that includes a silicon sensor. In one or more embodiments, the sensors 272, 273 respectively include an optical sensor, such as an optical pyrometer. The measurement assembly 270 includes an energy source 274 (e.g., a light source) and the sensor 276. The sensors 272, 273, the energy source 274, and the sensor 276 are disposed above the substrate 50. A lower temperature sensor 278 is disposed below the substrate 50. The energy source 274 is positioned to emit an energy toward a surface (such as a top surface 150 of the substrate 50), and the sensor 276 is disposed adjacent to the energy source 274 and positioned to receive the emitted energy that is reflected off of the substrate 50.

The energy source 274 can emit, for example, infrared light and/or ultraviolet light. In one or more embodiments, the energy source 274 is a laser light source with a controlled intensity and wavelength range. In one or more embodiments, a broadband light source is used. The energy source 274 may be a diode laser or an optical cable. When the energy source 274 is an optical cable, the optical cable is connected to an independent energy source (e.g., light source), which may be disposed near the process chamber 101. The energy source 274 may be a bundle of lasers or optical cables, such that a plurality of beams (e.g., light beams) are focused into a beam 282 (e.g., a light beam). In one or more embodiments, the energy source 274 can emit radiation at a varying wavelength range. The use of a varying wavelength range eliminates noise that may be caused by the use of a wider wavelength spectrum and allows for an increase in the strength of emission of the narrower range from the energy source 274 to increase the signal strength received by the sensor 276. In one or more embodiments, one or more of the heat sources 164A are used as the energy source 274. In one or more embodiments, the energy source 274 may be classified as a radiation source, such as a thermal radiation source or a broadband radiation source. The radiation source may be a laser diode or an optical assembly. The optical assembly may include a laser, a lamp, and/or a bulb, and/or a plurality of lenses, mirrors, or a combination of lenses and mirrors.

The sensor 276 measures the intensity of different wavelengths of energy (e.g., light) within a second beam 284 (e.g., second light beam), which is reflected off the substrate 50. The sensor 276 can be configured to measure an intensity of the second beam 284. The sensor 276 may include several optical components disposed therein in order to separate and measure the second beam 284. In one or more embodiments, the sensor 276 is a scanning band edge detector and scans through a An optional filter may be placed between the sensor 276 and the substrate support 120 and configured to filter out radiation emitted by the heat sources 164A, 164B.

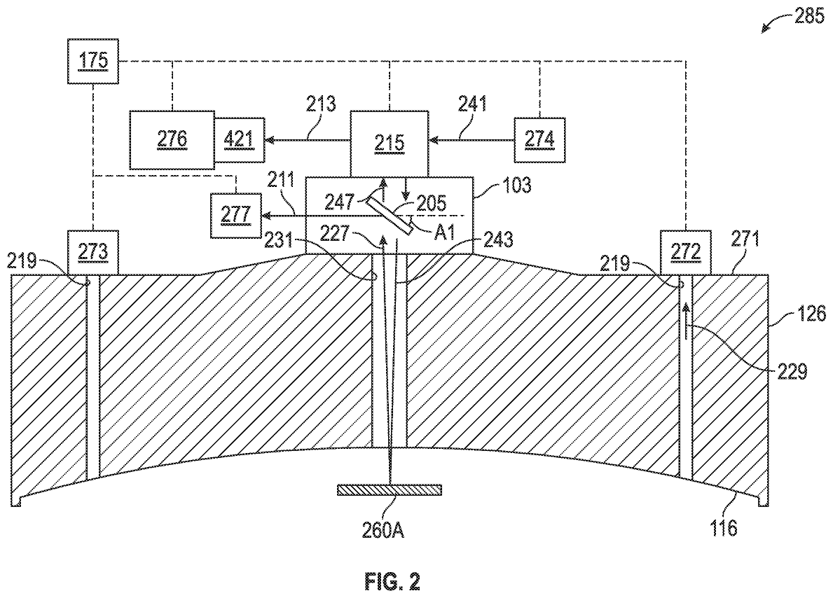

FIG. 2 is a partial schematic cross-sectional view of an in-situ reflectometry system (ISR) 285 that can be used as at least part of the measurement assembly 270, according to one or more embodiments. The present disclosure contemplates that other configurations may be used for the measurement assembly 270, for example other than reflectometers. The ISR System 285 includes the energy source 274, a collimator 215, the sensor 276, the second sensor 272, the third sensor 273, and a dichroic mirror 205 coupled to or disposed above the chamber lid 271. The ISR System 285 facilitates measurement of one or more properties of the substrate 50 (and/or a film disposed thereon). Example properties include temperature, film growth rate, thickness of a film, thin film optical properties and/or in-film concentration (e.g., Ge concentration and/or a dopant concentration, such as of phosphorus). The collimator 215 can be spaced from the dichroic mirror 205 by a distance within a range of 200 nm to 800 nm. Other distances are contemplated.

The energy source 274 is configured to generate energy 241 (e.g., radiation, such as light). For example, the energy source 274 could be a flash lamp, capable of producing full spectrum or partial spectrum light. In one or more embodiments, the spectrum of light generated has a wavelength between about 200 nm to about 4 micrometers, such as 200 nm to about 800 nm and/or 3 micrometers to 4 micrometers. Full spectrum light can allow for a wide range of light signals for analysis, however in one or more embodiments a light source may be limited to a specific wavelength of light or specific range of light wavelengths to accomplish the analysis. The energy source 274 may be controlled by the controller 175. The energy source 274 is in optical communication with the collimator 215, and directs energy 241 to the collimator 215 upon instruction of the controller 175. Optical communication includes connection by a fiber optic cable, and other modes of light transmission are contemplated. The travel path of the energy from the energy source 274 may be referred to as a propagation path. The collimated energy 243 (e.g., radiation, such as light, for example a light beam) leaves the collimator 215, and travels through a passage 231. In one or more embodiments, the passage 231 includes a light pipe. The passage 231 can be a made of any material capable of transmitting light of predetermined wavelengths, for example, sapphire. The passage 231 directs the collimated energy 243 to the surface of the substrate 50 (or a film thereon) to facilitate measurement of one or more properties of the substrate 50 (or a thin film thereon).

The collimated energy 243 is reflected off the target measurement surface, such as the substrate 50, and is reflected back as reflected energy 227. The reflected energy 227 travels back through the passage 231. The reflected energy 227 leaves the passage 231 and travels to the dichroic mirror 205 aligned with the passage 231 along the travel path of the reflected energy 227. In one or more embodiments, the dichroic mirror 205 includes a transparent material with a dielectric coating. The dielectric coating may include, but is not limited to, magnesium fluoride, tantalum pentoxide, and/or titanium dioxide. The ISR 285 can include an additional sensor 277 (which can be referred to as a second sensor). In one or more embodiments, the additional sensor 277 includes a pyrometer that includes a silicon sensor. In one or more embodiments, the additional sensor 277 includes an optical sensor, such as an optical pyrometer.

The dichroic mirror 205 reflects certain wavelengths of energy (e.g., light) away to the upper temperature sensor 277, but allows other specifically selected wavelengths to pass through to the collimator 215. A wavelength range directed to the sensor 276 through the collimator 215 may be between about, 100 nm and about 1000 nm, such as within a range of 200 nm and 800 nm, such as within a range of 200 nm and 400 nm, and such as within a range of 400 nm and 800 nm. Other wavelengths are contemplated. The dichroic mirror 205 facilitates multiple light based sensors to be used by directing light of a first desired range of to one sensor (such as the sensor 276) with the remaining light wavelengths being sent to at least another sensor (such as the additional sensor 277). Thus, use of optical spectrometer(s) and/or the ISR system 285 facilitates a compact measurement system, allowing more sensors to be included in a smaller footprint. The dichroic mirror 205 is arranged, or oriented, at an angle of incidence A1 between about, 30° and about 60°, such as within a range of 35° and 55°, with a plane near orthogonal to a longitudinal axis of the passage 231. However, other angles of incidence are contemplated.

As shown in FIG. 2, light reflected from the dichroic mirror 205 is transmitted to the additional sensor 277 along an energy path 211 (e.g., a light path). In one or more embodiments, light wavelengths between about 1.0 μm and about 6.0 μm, such as between about 3.0 μm and about 4.0 μm, travel along the energy path 211 to the additional sensor 277. As noted above, properties of the dichroic mirror 205 are selected to transmit or reflect light in specified wavelength ranges. Energy 247 (e.g., light) allowed to pass through the dichroic mirror 205 is collimated by the collimator 215. The collimated energy 213 is directed to the sensor 276. In one or more embodiments, the sensor 276 includes an optical spectrometer, such as a spectrograph configured to measure wavelength-resolved intensity. The sensor 276 can include a grating, an optical lens, a filter 421 and/or a linear-array photodiode detector. The filter 421 can be a short pass filter to limit the noise from a heat source (such as the heat sources 164A, 164B), or a dielectric filter. A dielectric filter includes any thin film based filters than can reduce or prevent specific wavelength of light from passing therethrough. While the filter 421 is described as part of the sensor 276, it is contemplated that the filter can be located in other locations. For example, the filter 421 can be part of the dichroic mirror 205. The filter 421 is configured to allow light of a specified wavelength to pass therethrough, while reducing or preventing passing or other wavelengths. In one or more embodiments, the filter 421 allows light of wavelengths below 550 nm to pass therethrough (while filtering other wavelengths) to mitigate light signal noise from heat sources of the process chamber, thus improving measurement accuracy. It is contemplated that the filter 421 can be placed in any light path that includes the light reflected off the substrate 50 (e.g., reflected energy 227 to the sensor 276, reflected energy 247 from dichroic mirror 205, and/or collimated energy 243). In one or more embodiments, the filter 421 is an integral component of the sensor 276. In one or more embodiments, the filter 421 is a standalone component from the sensor 276. In one or more embodiments, the filter 421 is not included in the path. It is to be noted that while one or more embodiments described herein may include a filter 421 and/or a dichroic mirror 205, both the filter 421 and the mirror 205 are optional and may be excluded from any embodiment or implementation described herein.

An optical spectrometer system and/or the ISR system 285 may optionally include the second sensor 272 and/or the third sensor 273 positioned outwardly of the additional sensor 277. The second sensor 272 and/or the third sensor 273 respectively are configured to be in line (e.g., vertically and/or optically aligned) with an outer passage 219. The outer passages 219 extend between a bottom surface and an upper surface of the chamber lid 271. The outer passages 219 may be sealed at upper and lower ends thereof by a material capable of transmitting energy 229 (e.g., light), such as quartz or sapphire. In one or more embodiments, each outer passage 219 includes a fiber optic cable disposed thereon.

In one or more embodiments, the second sensor 272 and/or the third sensor 273 respectively include an energy source (similar to the energy source 274), a collimator (similar to the collimator 215), a housing (similar to a housing 103), a mirror (similar to the dichroic mirror 205), a filter (similar to the filter 421), a sensor (similar to the sensor 276), and/or an additional sensor (similar to the additional sensor 277).

For each sensor 272, 273, the reflected signal travels back to the dichroic mirror and is split into multiple paths (e.g., propagation sub-paths). A first propagation sub-path directs reflected light to the respective additional sensor 277, while a second propagation sub-path directs reflected light to the collimator 215 and then to the sensor 276. The light intensity collected by the sensor 276 can be analyzed for true reflectance, which is compared with models, for example (Fresnel equations) using nonlinear fitting equations or other empirically derived equations to determine an emissivity (e.g., using a reflectance) of the substrate 50. The additional sensor 277 can measure a temperature of the substrate 50. The second sensor 272 and/or the third sensor 273 are configured to measure a growth rate and/or a temperature of an outer region of the substrate 50, an outer region of the substrate support 120, and/or the pre-heat ring 114.

In one or more embodiments, models are empirically derived by obtaining absorption/reflectance data for light at predetermined wavelengths for various materials of the substrate 50 and/or other processed substrates. The data may be collected at conditions that approximate those of a predetermined recipe for processing future substrates, such as a process recipe at which the model will be used. The data is then fit to an equation, such as a non-linear equation. Light received by the sensor 276 is analyzed for intensity (e.g., true reflectance of light reflected from the measured substrate 50) and fit to the empirically derived equation to determine the emissivity of the substrate 50. Stated otherwise, the amount of light reflected from the top surface 150 of the substrate 50 changes depending upon the material of film on the substrate 50 and/or a thickness of the material of the film. The amount of light can be compared to known data to determine the emissivity and/or a shift in emissivity. This data and/or equations may also take into account other optical properties, such as refractive index and/or extinction coefficient, to facilitate measurement accuracy. The substrate support 120 can rotate the substrate 50 such that measurements are taken at a plurality of azimuthal locations on the substrate 50 and/or the substrate support 120. The present disclosure contemplates that a plurality of emissivity measurements (for the same substrate or across a variety of substrates) can be averaged for an adjusted emissivity (e.g., a correction value) to be applied to emissivity measurements.

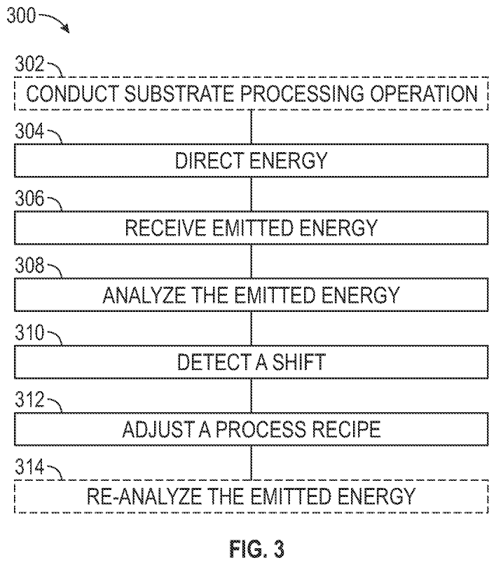

FIG. 3 is a schematic flow diagram view of a method 300 of monitoring substrate processing, according to one or more embodiments.

Optional operation 302 includes conducting a substrate processing operation. The substrate processing operation may include a deposition process on a substrate and/or an etching process on the substrate. The substrate processing operation may further include heating the substrate, introducing at least one process gas, introducing a purge gas, and evacuating the process and purge gases. A single substrate or a plurality of substrates can be processed during the substrate processing operation.

Operation 304 includes directing energy from an energy source toward a surface in a processing chamber. The surface can be part, for example, of the substrate 50, the substrate support 106, or the preheat ring 114. In one or more embodiments, the energy includes a collimated light beam.

Operation 306 includes receiving emitted energy using a sensor. In one or more embodiments, the emitted energy includes a reflected light beam of the collimated light beam reflected off of the surface.

Operation 308 includes analyzing the emitted energy. The analyzing of the emitted energy includes measuring an emissivity of the emitted energy, using the sensor, over the time period to generate a signal profile. The measured emissivity versus time can be plotted to generate the signal profile. The emissivity can be measured, for example, by measuring a reflectivity of the surface. In one or more embodiments, the sensor is a spectrometer. The emissivity can indicate a condition on the substrate. The condition can include for example one or more of a material concentration of a film, a film thickness, a film growth rate, an etching rate, or a selectivity of film growth or etching.

Operation 310 includes detecting a shift in the emitted energy over the time period. In one or more embodiments, the shift is detected along a shift section of the signal profile of the emitted energy. In one or more embodiments, the detection of the shift includes comparing the signal profile to a reference profile to identify a deviation of the shift section of the signal profile relative to a corresponding section of the reference profile. The comparing can include a signal difference, such as by signal subtraction. The reference profile can be generated, for example, using a previous iteration of the substrate processing operation of operation 302. The reference profile can be saved in a memory (such as the memory 176 of the controller 175), and the method 300 can retrieve the reference profile from the memory. The signal profile(s) generated in the method 300 can be saved to be used as reference profile(s) for subsequent iterations of the method 300. Fingerprinting can be used (e.g., by a user and/or the controller 175) to save acceptable signal profiles for subsequent use as reference profiles, and to delete rejected signal profiles. Downstream testing (such as metrology data) can be used to accept or reject signal profiles.

In one or more embodiments, the deviation includes a change in direction or a value difference exceeding a threshold. As an example, a signal increase in reflectance can indicate that selectivity is lost in processing. In one or more embodiments, the analyzing includes line fitting the signal profile and the reference profile, and comparing the two line fittings. The line fitting can include linear fitting or polynomial fitting.

The present disclosure contemplates that the signal profile(s) and/or the reference profile(s) described herein can be represented, generated, and/or analyzed in the form of software without visually displaying (such as to a user on a display screen) the signal profile(s) and/or the reference profile(s). The present disclosure also contemplates that the signal profile(s) and/or the reference profile(s) can optionally be displayed (such as on a display screen to a user).

Operation 312 includes adjusting a process recipe. The process recipe that is adjusted can be, for example, the process recipe used in operation 302 and/or another process recipe. The process recipe is adjusted in response to the detection of the shift. In one or more embodiments, the process recipe is automatically adjusted (such as by using the controller 175) in response to the detection of the shift of operation 310. The adjusting of the process recipe can include, for example, adjusting one or more process parameters (such as time, temperature, pressure, gas flow rate, the composition(s) of gas(es), and/or the ratios of gases) of the process recipe.

Optional operation 314 includes, after the adjusting of the process recipe, re-analyzing the emitted energy at a process section corresponding to the shift section of the signal profile. The process section can be, for example, a section of the substrate processing operation that corresponds to the same timeframe as the shift section. In one or more embodiments, the emitted energy is re-analyzed at operation 314 to generate a second signal profile using the adjusted process recipe. Optional operation 314 can include the operations of operation 308 in relation to the second signal profile. If a second shift (similar to the shift of operation 310) is detected in the second signal profile then the process recipe can be adjusted again at operation 312 and operation 314 can be repeated to generate a third signal profile. Operations 312 and 314 can be repeated until a shift is no longer detected in the most recently generated signal profile, and the process recipe of the most recently generated signal profile can be used for subsequent processing. The most recently generated signal profile can be saved as an accepted profile to be used as a reference profile in operation 310. The present disclosure contemplates that a plurality of reference profiles that are saved can be merged (e.g., weighed and/or averaged) to generate a reference profile for use in operation 310.

The present disclosure contemplates that operations 302-314 can be conducted in a variety of sequences and/or simultaneously. As an example, operations 304, 306, 308 can be conducted simultaneously with operation 302. In one or more embodiments, operations 304, 306, 308 are continuously conducted throughout the substrate processing operation of operation 302.

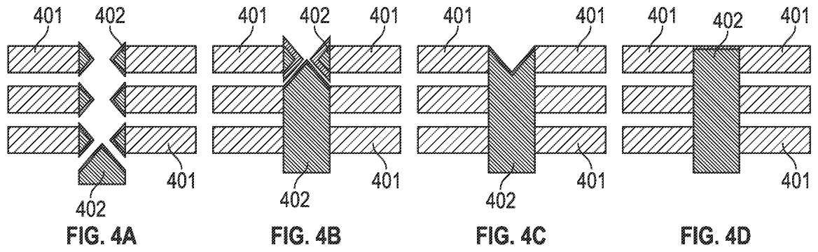

FIGS. 4A-4D schematically illustrate a process flow of a substrate processing operation, according to one or more embodiments. FIGS. 4A-4D can be used, for example, in operation 302 of the method 300. The substrate processing operation of FIGS. 4A-4D can form source/drain structures on a substrate.

FIG. 4A shows a device including ribbon structures respectively including crystalline silicon layers 401. At FIG. 4A, a dielectric material 402 is deposited on ends of the crystalline silicon layers 401 and in a trench between the ribbon structures. At FIG. 4A, the dielectric material 402 is formed using a first process recipe that includes a process gas including hydrochloric acid (HCl) at a flow ratio of about 50%.

FIGS. 4B and 4C shows continued deposition of the dielectric material 402 in the trench. The dielectric material 402 fills in the trench from the bottom without pinching off areas below dielectric material 402 on ends of the crystalline silicon layers 401 prior to the areas being filled in. For example, an open area below the two uppermost sections of dielectric material 402 in FIG. 4B is filled in (as shown in FIG. 4C) before the two uppermost sections are joined together using the dielectric material 402. At FIGS. 4B and 4C, the dielectric material 402 is formed using a second process recipe that includes a process gas including HCl at a flow ratio of about 100%.

FIG. 4D shows continued deposition of the dielectric material 402 in the trench to fill in the trench. At FIG. 4D, the dielectric material 402 is formed using a third process recipe that includes a process gas including HCl at a flow ratio of about 75%.

The method 300 of FIG. 3 can be used in relation to FIGS. 4A-4D to switch between the first process recipe, the second process recipe, and the third process recipe. For example, a shift can be detected in each respective process recipe to indicate that the dielectric material 402 has grown by a threshold thickness, and method 300 can automatically switch to the next process recipe and monitor the next process recipe for a shift.

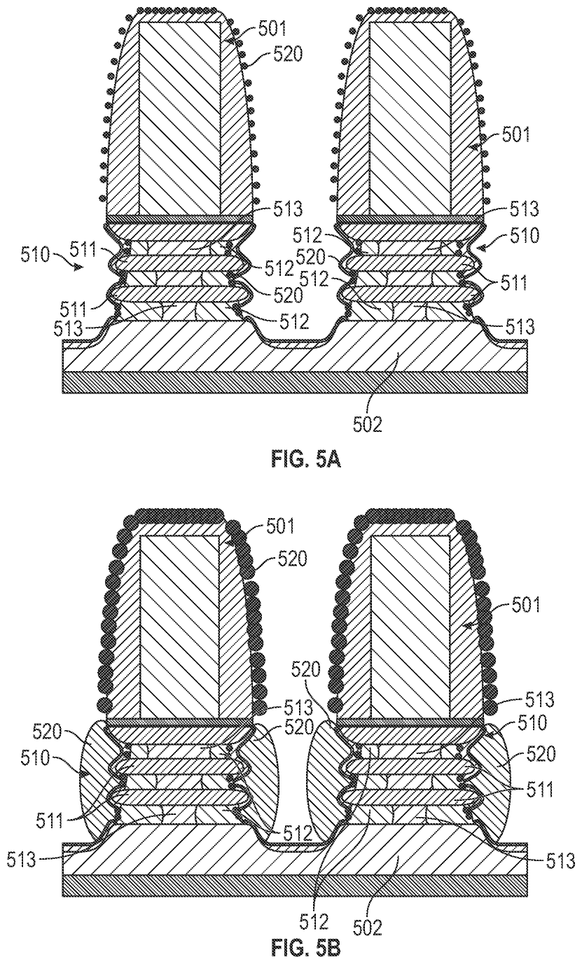

FIGS. 5A-5D schematically illustrate a process flow of a substrate processing operation, according to one or more embodiments. FIGS. 5A-5D can be used, for example, in operation 302 of the method 300.

FIGS. 5A and 5B show a device including a set of upper dielectric structures 501 and a set of lower dielectric structures 510 formed on a silicon substrate 502. The lower dielectric structures 510 respectively include dielectric spacers 512 disposed between ribbon structures including crystalline silicon layers 511 and the silicon substrate 502. The dielectric spacers 512 are disposed on sides of silicon-germanium (SiGe) layers 513.

At FIGS. 5A and 5B, a dielectric material 520 is deposited on ends of the crystalline silicon layers 511 and ends of the dielectric spacers 512. At FIGS. 5A and 5B, the dielectric material 520 is formed using a first process recipe that includes a process gas including hydrochloric acid (HCl) at a flow ratio of about 50%. In FIG. 5A, nodules of the dielectric material 520 are formed on the upper dielectric structure 501 and the lower dielectric structure 510. FIG. 5B shows continued deposition of the dielectric material 520 such that the nodules on the upper dielectric structure 501 are larger, and areas between the crystalline silicon layers 511 and outwardly of the dielectric spacers 512 are filled in without joining together adjacent sections of dielectric material 520 (e.g., to avoid pinch-off). In one or more embodiments, the dielectric material 520 includes silicon phosphorus (SiP). In one or more embodiments, the dielectric material 520 on the upper dielectric structures 501 is amorphous, and the dielectric material 520 on the lower dielectric structures 520 is crystalline. In FIGS. 5A and 5B the deposition can be relatively nonselective to facilitate enhanced dopant incorporation, higher growth rate, and/or higher silicon concentration, for example.

FIG. 5C shows etching of the dielectric material 520 to remove the nodules from the upper dielectric structure 501. The dielectric material 520 on the upper dielectric structure 501 is etched relative to the dielectric material 520 on the lower dielectric structure 510 such that dielectric material 520 remains on the lower dielectric structure 510. At FIG. 50, the dielectric material 520 is etched using a second process recipe that includes a process gas including HCl and omitting deposition gas (such as a silane-containing gas).

FIG. 5D shows selective deposition of the dielectric material 520 on the lower dielectric structures 510. At FIG. 5D, the dielectric material 520 is deposited using a third process recipe that includes a process gas including a deposition gas (such as a silane-containing gas) and HCl at a flow ratio of about 100%. In one or more embodiments, the deposition in FIG. 5D is about 100% selective and the deposition in FIGS. 5A and 5B are less than 100% selective.

The method 300 of FIG. 3 can be used in relation to FIGS. 5A-5D to switch between the first process recipe, the second process recipe, and the third process recipe. A shift can be detected in each respective process recipe to indicate that the dielectric material 520 has grown or reduced to a threshold thickness, and method 300 can automatically switch to the next process recipe and monitor the next process recipe for a shift.

As an example, the detected shift in FIG. 5B can indicate that the dielectric material 520 on the upper dielectric structure 501 has reached or surpassed a threshold thickness, and in response to the detection of the shift the first process recipe is adjusted to the second process recipe that etches the dielectric material 520 on the upper dielectric structure 501 relative to the dielectric material 520 on the lower dielectric structure 510. Then in FIG. 5C the method 300 can be repeated for the second process recipe to detect a second shift, and the second shift indicates that the dielectric material 520 on the upper dielectric structure 510 has reached or fallen below a second threshold thickness. The second threshold thickness can be, for example, about 0 mm. The second process recipe, in response to the detection of the second shift, can be adjusted to the third process recipe that selectively deposits the dielectric material 520 on the lower dielectric structure 510.

The dielectric material 520 can support the crystalline silicon layers 511, and the SiGe layers 513 can be subsequently removed. The method 300 can be used to monitor for an emissivity shift on the upper dielectric structure 501 to shift to remove the dielectric material 520 from the upper dielectric structure 501. The method 300 can be used to monitor for an emissivity shift that indicates the spaces outside of the dielectric spacers 512 and between the crystalline silicon layers 511 are filled with the dielectric material 520. The method 300 can be used to monitor for an emissivity shift that indicates pinch-off has occurred for the dielectric material 520.

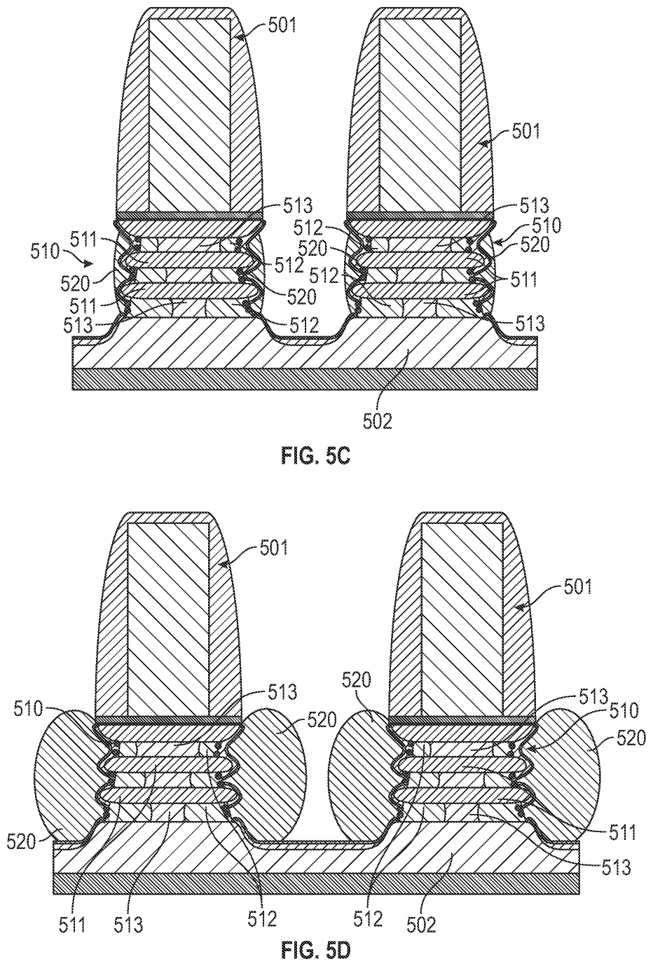

FIGS. 6A-6C schematically illustrate a process flow of a substrate processing operation, according to one or more embodiments. FIGS. 6A-6C can be used, for example, in operation 302 of the method 300.

FIG. 6A shows a device including a dielectric structure 601 formed on a silicon substrate 602. At FIG. 6A, a dielectric material 620 is formed in a nonselective (e.g., blanket) manner using a first process recipe.

FIG. 6B shows etching of the dielectric material 620 to remove the dielectric material 620 from the dielectric structure 601. At FIG. 6B, the dielectric material 620 is etched using a second process recipe that includes a process gas including HCl and omitting deposition gas (such as a silane-containing gas). In one or more embodiments, the dielectric material 620 includes silicon carbide (SIC). The etching can remove amorphous sections and poly-SiC sections from the dielectric material such that crystalline SiC remains.

FIGS. 6A and 6B can be repeated one or more times until the crystalline SiC reaches or surpasses a target thickness (such as shown in FIG. 6C). The crystalline SiC can include a dopant (such as phosphorus). The method 300 of FIG. 3 can be used in relation to FIGS. 6A-6C to switch between the first process recipe, the second process recipe, and repeated iterations thereof. A shift can be detected in each respective process recipe to indicate that the dielectric material 620 has grown or reduced to a threshold thickness, and method 300 can automatically switch to the next process recipe and monitor the next process recipe for a shift.

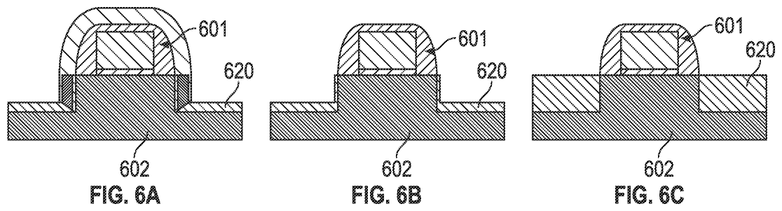

FIGS. 7A-7C schematically illustrate a process flow of a substrate processing operation, according to one or more embodiments. FIGS. 7A-7C can be used, for example, in operation 302 of the method 300.

FIG. 7A shows a device including a first layer 701 deposited on a silicon substrate 702 and a second layer 703 deposited on the first layer 701 using a first process recipe, such as in a nonselective (e.g., blanket) manner. The first layer 701 includes a material (such as silicon) and a dopant (such as phosphorus). The second layer 703 includes the material (such as silicon). In FIG. 7A the deposition can occur at a relatively low temperature, such as a temperature below 500 degrees Celsius.

FIG. 7B shows etching of the second layer 703 to remove the second layer 703. At FIG. 6B, the dielectric material 620 is etched (e.g., selectively) using a second process recipe that includes a process gas including HCl and omitting deposition gas (such as a silane-containing gas).

FIGS. 7A and 7B can be repeated one or more times (such as four times as shown in FIG. 7C) until a device structure is established. The method 300 of FIG. 3 can be used in relation to FIGS. 7A-7C to switch between the first process recipe, the second process recipe, and repeated iterations thereof. A shift can be detected in each respective process recipe to indicate that the second layer 703 has grown or reduced to a threshold thickness, and method 300 can automatically switch to the next process recipe and monitor the next process recipe for a shift. For example, the shift can indicate that the material of the second layer 703 has reached or surpassed a threshold thickness in FIG. 7A, and in response to the detection of the shift the first process recipe is adjusted to the second process recipe that etches the material of the second layer 703 (as shown in FIG. 7B).

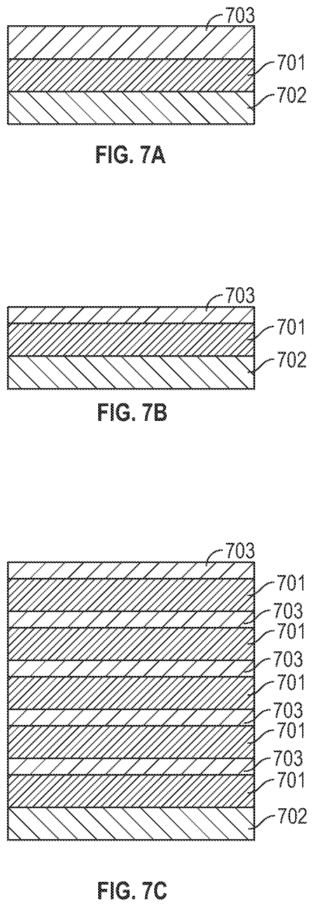

FIG. 8 is a schematic graphical view of a reference profile 801, according to one or more embodiments. The reference profile 801 is line-fit to generate a line-fit reference profile 802. The reference profile 801 and/or the line-fit reference profile 802 can be used, for example, in operation 310 of the method 300.

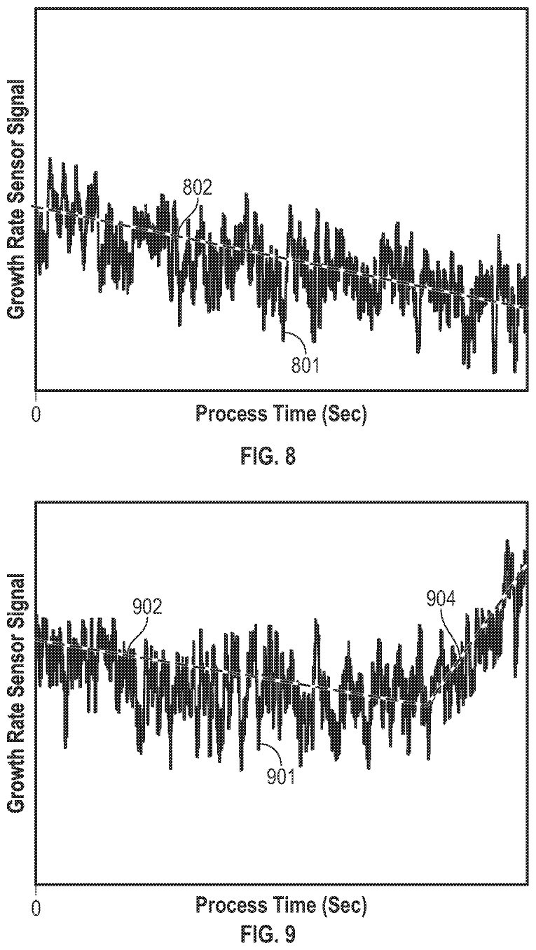

FIG. 9 is a schematic graphical view of a signal profile 901, according to one or more embodiments. The signal profile 901 is line-fit to generate a line-fit signal profile 902. The signal profile 901 and/or the line-fit signal profile 902 can be used, for example, in operation 308 of the method 300. As shown in FIG. 9, the line-fit signal profile 902 includes a shift section 904 that includes a deviation (e.g., a change in direction). The shift section 904 can indicate, for example, a loss in selectivity during selective film growth.

The profiles described herein (such as the reference profile 801 and/or the signal profile 901) can be fed into a feedback control loop (such as of the controller 175) to adjust process recipe(s).

Benefits of the present disclosure include accurate monitoring and adjustment (e.g., optimizing) of process parameters of process recipes; adjustment of process parameters of process recipes that account for aging and wear of chamber components; and adjustment of process parameters of process recipes in a manner that is real-time and in-situ. Benefits also include reduced or eliminated opening of process chambers and machine down time, enhanced dopant incorporation, higher growth rate, and/or higher material (e.g., silicon) concentration. Such benefits can be used to facilitate selectivity in relation to dielectric surfaces and/or high aspect ratio structures, for example.

It is contemplated that one or more aspects disclosed herein may be combined. As an example, one or more aspects, features, components, operations and/or properties of the processing system 100, the process chamber 101, the controller 175, the measurement assembly 270, the ISR 285, the method 300, the substrate processing operation of FIGS. 4A-4D, the substrate processing operation of FIGS. 5A-5D, the substrate processing operation of FIGS. 6A-6C, the substrate processing operation of FIGS. 7A-7C, the profile(s) of FIG. 8, and/or the profile(s) of FIG. 9 may be combined. Moreover, it is contemplated that one or more aspects disclosed herein may include some or all of the aforementioned benefits.

While the foregoing is directed to examples of the present disclosure, other and further examples of the disclosure may be devised without departing from the basic scope thereof, and the scope thereof is determined by the claims that follow.

What is claimed is:

1. A system for processing substrates, the system comprising:
a chamber body at least partially defining a processing volume;
one or more heat sources operable to heat the processing volume;
a substrate support disposed in the processing volume; and
a sensor operable to measure an emissivity in the processing volume;
a controller comprising instructions that, when executed by a processor, cause a plurality of operations to be conducted, the plurality of operations comprising:
analyzing the measured emissivity for a time period, the analyzing comprising generating a signal profile of the measured emissivity over the time period;
detecting a shift in the signal profile along a shift section of the signal profile; and
adjusting a process parameter in response to the detection of the shift.

2. The system of claim 1, wherein the emissivity indicates one or more of a material concentration of a film, a film thickness, or a selectivity, and the sensor is operable to continuously measure the emissivity during a substrate processing operation.

3. The system of claim 1, wherein the process parameter is automatically adjusted in response to the detection of the shift, and the plurality of operations further comprise after the adjusting of the process parameter, re-analyzing the measured emissivity at a process section corresponding to the shift section of the signal profile.

4. A method of monitoring substrate processing, comprising:
directing energy from an energy source toward a surface in a processing chamber;
receiving emitted energy using a sensor;
analyzing the emitted energy for a time period, the analyzing comprising:
measuring an emissivity of the emitted energy over the time period to generate a signal profile;
detecting a shift in the emitted energy over the time period; and
adjusting a process recipe in response to the shift in the emitted energy.

5. The method of claim 4, wherein the shift is detected along a shift section of the signal profile.

6. The method of claim 5, further comprising after the adjusting of the process recipe, re-analyzing the emitted energy at a process section corresponding to the shift section of the signal profile.

7. The method of claim 5, wherein the measuring of the emissivity is conducted using a spectrometer.

8. The method of claim 7, wherein the energy includes a collimated light beam, and the emitted energy includes a reflected light beam of the collimated light beam reflected off of the surface.

9. The method of claim 5, wherein the detection of the shift comprises comparing the signal profile to a reference profile to identify a deviation of the shift section of the signal profile relative to a corresponding section of the reference profile.

10. The method of claim 9, wherein the deviation includes a change in direction or a value difference exceeding a threshold.

11. The method of claim 9, wherein the analyzing comprises line fitting the signal profile and the reference profile.

12. The method of claim 4, further comprising depositing a material on an upper dielectric structure and a lower dielectric structure using the process recipe, wherein the shift indicates that the material on the upper dielectric structure has reached or surpassed a threshold thickness, and in response to the detection of the shift the process recipe is adjusted to a second process recipe that etches the material on the upper dielectric structure relative to the material on the lower dielectric structure.

13. The method of claim 12, further comprising:
repeating the directing of the energy and the receiving of the emitted energy;
analyzing the emitted energy for a second time period;
detecting a second shift in the emitted energy over the second time period, wherein the second shift indicates that the material on the upper dielectric structure has reached or fallen below a second threshold thickness; and
adjusting the second process recipe in response to the detection of the second shift, wherein the second process recipe is adjusted to a third process recipe that selectively deposits the material on the lower dielectric structure.

14. The method of claim 4, further comprising:
depositing a first layer on a substrate using the process recipe, the first layer including a material and a dopant; and
depositing a second layer on the first layer, the second layer including the material, wherein the shift indicates that the material of the second layer has reached or surpassed a threshold thickness, and in response to the detection of the shift the process recipe is adjusted to a second process recipe that etches the material of the second layer.

15. A non-transitory computer readable medium comprising instructions that, when executed, cause a plurality of operations to be conducted, the plurality of operations comprising:
measuring an emissivity over a time period to generate a signal profile;
detecting a shift in the signal profile along a shift section of the signal profile; and
adjusting a process parameter in response to the detection of the shift.

16. The non-transitory computer readable medium of claim 15, wherein the process parameter is automatically adjusted in response to the detection of the shift, and the plurality of operations further comprise after the adjusting of the process parameter, re-analyzing the measured emissivity at a process section corresponding to the shift section of the signal profile.

17. The non-transitory computer readable medium of claim 15, wherein the detection of the shift comprises comparing the signal profile to a reference profile to identify a deviation of the shift section of the signal profile relative to a corresponding section of the reference profile.

18. The non-transitory computer readable medium of claim 17, wherein the deviation includes a change in direction or a value difference exceeding a threshold.

19. The non-transitory computer readable medium of claim 17, further comprising line fitting the signal profile and the reference profile.

20. The non-transitory computer readable medium of claim 17, wherein the reference profile is saved in a memory.
